(19) United States
(12) Patent Application Publication
(10) Pub. No.: US 2009/0288704 A1
(43) Pub. Date: Nov. 26, 2009

(54) NITRIDED BARRIER LAYERS FOR SOLAR CELLS

(75) Inventor: Peter G. BORDEN, San Mateo, CA (US)

Correspondence Address: APPLIED MATERIALS;C/O PILLSBURY WINTHROP SHAW PITTMAN LLP, P .O . BOX 10500, MCLEAN, VA, 22120, US

(73) Assignee: Applied Materials, Inc.

(21) Appl. No.: 12/421,563

(22) Filed: Apr. 9, 2009

Related U.S. Application Data
(60) Provisional application No. 61/043,664, filed on Apr. 9, 2008.
(60) Provisional application No. 61/043,675, filed on Apr. 9, 2008.

(51) Int. Cl. H01L 31/0368; H01L 31/18

(52) U.S. Cl. 136/255; 136/256; 438/97; 257/E31.043

(57) ABSTRACT

The present invention relates to polysilicon emitter solar cells, and more particularly to polysilicon emitter solar cells with hyperabrupt junctions, and methods for making such solar cells. According to one aspect, a polysilicon emitter solar cell according to the invention includes a nitrided tunnel insulator. The nitridation prevents boron diffusion, enabling a hyperabrupt junction for a p-poly on n-Si device. According to another aspect, a nitrided oxide (DPN) is used in a tunnel oxide layer of a MIS solar cell structure. The DPN layer minimizes plasma damage, resulting in improved interface properties. An overlying polysilicon emitter can then provide a low sheet resistance emitter without heavy doping effects in the substrate, excess recombination, or absorption, and is a significant improvement over a conventional diffused emitter or TCO. According to another aspect, the invention includes a method for making a solar cell structure that is functionally equivalent to a selective emitter, but without the requirement for multiple diffusions, long diffusions, aligned lithography, or fine contact holes.

### CROSS-REFERENCE TO RELATED APPLICATIONS

The present application claims priority to U.S. Prov. Appln. No. 61/043,664 and U.S. Prov. Appln. No. 61/043,675, the contents of both being incorporated by reference herein in their entirety.

### FIELD OF TITLE INVENTION

The present invention relates to solar cells, and more particularly to solar cells with nitrided junctions.

### BACKGROUND

Many types of solar cells have structures that could be improved with better junction and contact properties due to the materials used and/or their fabrication processes.

For example, polysilicon emitter solar cells were demonstrated in the early '80s. These typically consist of polysilicon deposited on a thin tunnel dielectric such as SiO₂. The dielectric is supposed to serve two functions. First, it is intended to passivate the interface between the poly and the substrate. Second, it is intended to block diffusion to form a hyperabrupt junction.

However, these devices were not commercialized. This is partly because it is much easier to obtain long lifetime n-type silicon at low cost. In that case the polysilicon must be boron doped to create a p-type poly, and a thin SiO₂ layer will not stop boron diffusion. This is a problem because the polysilicon is formed in two steps. In the first, it is deposited at a relatively low temperature, typically 650-700° C. The boron diffusion is negligible at this point. However, the poly must then be annealed, typically at >900° C. for about 30 seconds, in order to densify it. The densification reduces the sheet resistance of the layer to useful values (typically <200 ohms/square) and also reduces optical absorption. At the densification time/temperature, the boron diffuses substantially, which results in a conventional p-n junction solar cell without a hyperabrupt junction. Therefore, polysilicon solar cells with hyperabrupt junctions could not be achieved.

A similar type of high efficiency single-junction solar cells, reaching 24.7% efficiency, use a selective emitter structure such as that shown in FIG. 1. (See A. Aberle, Crystalline Silicon Solar Cells: Advanced Passivation and Analysis, UNSW Books, Sydney, 1999). The selective emitter consists of a shallow, moderately doped diffusion 106 in the areas between the contacts 102 (on the order of 0.3 μm thick, 10¹⁹/cm³ doping), and a deep, highly doped region 108 under the contacts (on the order of 1-3 μm deep and doped 5×10¹⁹/cm³). The contact openings through coating 104 are 2-3 μm wide, and the metal grid lines 102 are aligned over these small openings. The narrow contacts are needed to minimize the metal contact area with the surface, as this contact region causes high carrier recombination.

This structure is complex to fabricate for a number of reasons. First, the deep diffusion must be done in a process step separate from the shallow diffusion, and can require several hours diffusion time. Second, the contact holes and contact lines must be lithographically aligned to the deep diffusions. This precise lithography is costly and slow. Third, small contact holes are needed, forcing use of high resolution lithography.

Another type of known solar cell is the MIS type solar cell (see Sze, Physics of Semiconductor Devices, second edition, Wiley, 1981, page 820). These devices can be combined with polysilicon contacts to provide the proper work function (see Green, Solar Cells: Advanced Principles & Practice, Center for Photovoltaic Devices and Systems, University of New South Wales, Sydney, 1995, pp. 181-186 and 212-214).

The MIS solar cell structure is shown in FIG. 2A. It consists of a thin tunnel oxide 204—typically 15 Å thick over a p-type substrate 202. Front contact fingers 206 are formed over the oxide, using either metal or polysilicon, with the latter preferred to avoid pinning the Fermi level of the surface. The substrate under the tunnel oxide may also be doped in order to provide lateral conductivity and reducing surface recombination. Back contacts 208 are formed to complete the device.

A problem with this device structure is shown in FIG. 2B, which graphically depicts the junction characteristics. As mentioned above, SiO₂ in layer 204 is a poor diffusion barrier. Consequently, dopant atoms from the polysilicon contact 206 will diffuse into the underlying silicon 202. For example, if the polysilicon is N-type and doped with phosphorous, then the phosphorous will diffuse through the thin SiO₂ during growth of the polysilicon, causing the underlying silicon to be N-type as well. Consequently, there will be a relatively small field 210 across the SiO₂ as shown in FIG. 2B. As the tunneling current is an exponential function of this field, the thin SiO₂ will thus cause a series resistance that reduces cell fill factor and efficiency.

Another problem of the prior art MIS cell is that the layers such as the polysilicon and thin SiO₂ were formed in diffusion furnaces, where the wafers are held vertically in slotted boats. This is adequate for thicker wafers (>200 μm thickness), but will result in unacceptable breakage for thinner wafers.

Therefore, there is an opportunity for improvement to form a tunnel dielectric that prevents diffusion in order to increase the field across the dielectric, and for processes that allow formation of layers with wafers on planar susceptors. Moreover, there remains a need in the art for a less complex structure and technique for forming point contacts in a solar cell. Still further, there remains a need in the art for polysilicon emitter and other types of solar cells with hyperabrupt junctions, and methods for making the same.

### SUMMARY

The present invention relates to polysilicon and shallow emitter solar cells, and more particularly to such types of solar cells with hyperabrupt junctions, and methods for making such solar cells. According to one aspect, a polysilicon emitter solar cell according to the invention includes a nitrided tunnel insulator. The nitridation prevents boron diffusion, enabling a hyperabrupt junction for a p-poly on n-Si device. One favorable result is a very low reverse saturation current device on a low cost substrate. A nitrided oxide is used as a diffusion barrier to enable use of a polysilicon emitter.

According to another aspect, a nitrided oxide (DPN) is used in a tunnel oxide layer of a MIS solar cell structure. The DPN layer minimizes plasma damage, resulting in improved interface properties. An overlying polysilicon emitter can then provide a low sheet resistance emitter without heavy doping effects in the substrate, excess recombination, or absorption, and is a significant improvement over a conventional diffused emitter or TCO. The films for the MIS structure can be formed using planar processes suitable for thin wafers that could not be stacked in a diffusion tube, as is done conventionally. The combination of a DPN oxide and polysilicon emitter results in a high doping gradient across the DPN oxide, and, therefore, a high field to reduce series resistance. The DPN film may be charged to create surface inversion or control surface carrier concentration, obviating the need for doping the substrate. The substrate surface may be counter doped to increase the tunneling field (and current) across the MIS oxide.

The present invention further relates to methods and apparatuses for improved emitter contacts for solar cells. According to another aspect, the invention includes a method for making a solar cell structure that is functionally equivalent to a selective emitter, but without the requirement for multiple diffusions, long diffusions, aligned lithography, or fine contact holes.

In furtherance of these and other aspects, a solar cell according to some embodiments of the invention comprises a substrate, a tunnel dielectric that is nitrided formed over the substrate, and a doped polysilicon layer formed over the nitrided tunnel dielectric.

In additional furtherance of these and other aspects, a solar cell emitter contact according to some embodiments of the invention comprises a dielectric layer formed over an emitter having an opening formed therein; a nitrided layer formed over the dielectric layer and in the opening; a polysilicon layer overlapping the opening; and metallization in contact with the polysilicon layer.

In yet additional furtherance of these and other aspects, a MIS solar cell according to some embodiments of the invention comprises a substrate; a polysilicon layer over the substrate; an insulating layer between the substrate and the polysilicon layer that includes a nitrided diffusion barrier to prevent diffusion from the gate into the substrate.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 shows a selective emitter structure in conventional high efficiency solar cells;

FIGS. 2A and 2B illustrate certain properties of an emitter structure in conventional high efficiency MIS type solar cells;

FIG. 3 shows a polysilicon emitter solar cell structure according to embodiments of the invention;

FIG. 4 shows a process flow for making a polysilicon emitter solar cell having a hyperabrupt junction according to embodiments of the invention;

FIG. 5 shows an improved emitter contact structure for a solar cell according to embodiments of the invention;

FIGS. 6A and 6B show process flows for a conventional solar cell structure and a solar cell structure according to embodiments of the invention, respectively; and

FIGS. 7A and 7B illustrate certain properties of an emitter structure with underlying nitrided layer in MIS type solar cells according to embodiments of the invention.

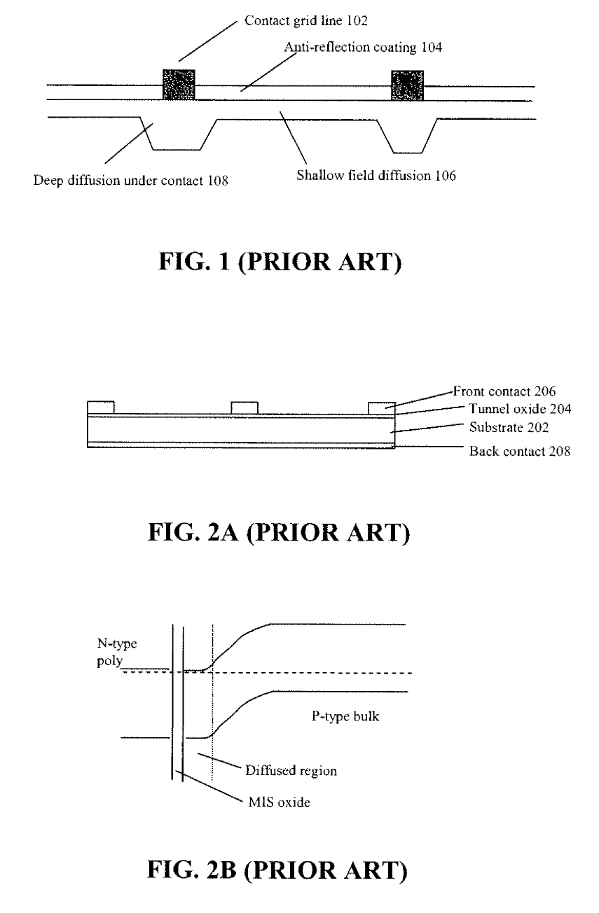

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The present invention recognizes that hyperabrupt junctions provide improved efficiency in solar cells because the open circuit voltage is related to the log of the ratio of the light-generated current, J_{L}, to the reverse saturation current, J₀, as

V_{oc}=kT/q ln(J_{L}/J₀+1)

Where the reverse saturation current is given by

J₀=q(Dₙnₚ/Lₙ+Dₚpₙ/Lₚ)

where D is the minority carrier diffusivity, n(p) is the minority carrier concentration, and L is the diffusion length. For example, in the case of p-type poly on a low doped n-type substrate, the poly is heavily doped, so the minority carrier concentration, nₚ, is essentially zero. Therefore, only the second term contributes to the J₀. Very low values can be achieved, as the value of L is large.

The present inventors further recognize that silicon nitride and silicon oxy-nitride layers can be used to block boron diffusion. These can be formed either by growing a silicon dioxide layer and implanting nitrogen to form an oxynitride, or by thermally growing a silicon nitride layer on silicon or on a very thin SiO₂ base.

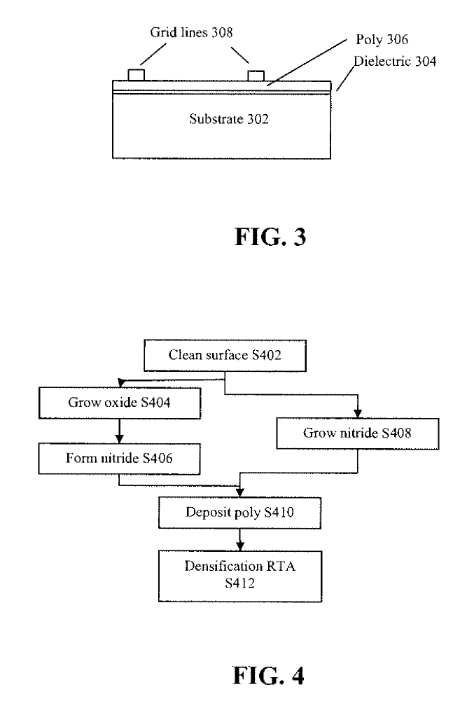

Accordingly, in one embodiment, the present invention forms a polysilicon emitter solar cell with improved junction properties, as shown in FIG. 3. As shown in FIG. 3, the solar cell consists of a junction formed through deposition of a nitrided gate tunnel insulator 304 under a boron doped polysilicon layer 306 and on top of a p-type substrate 302. In contrast to the gate stack on an MOS transistor, the nitride layer covers the full surface of the solar cell. Grid lines 308 complete the top surface of the cell.

An aspect of the invention is the use of the nitrided gate insulator layer 304 instead of silicon dioxide. The nitrided insulator blocks boron diffusion, providing an abrupt junction even with use of a thermal densification step. The densification step is advantageous for two reasons. First, it reduces the resistivity of the polysilicon 306 so that it can be used to conduct current to contact grid lines 308. Second, it reduces the optical absorption of the polysilicon. Although the polysilicon emitter solar cell and nitrided gate oxide are both known in the art, these elements have existed for over a decade without this combination having appeared in the prior art for the solar cell application. In fact, as recently as 2006 a U.S. application was filed (U.S. Patent Pub. 2007/0256728) explicitly referring to use of a tunnel oxide with no mention of a nitrided tunnel dielectric, and explicitly avoiding high temperature steps in the description of the specification.

FIG. 4 shows an example process flow according to this embodiment of the invention. After the surface of a silicon substrate is cleaned in step S402, a tunnel insulator layer is formed. According to the invention, silicon nitride and silicon oxy-nitride layers for the tunnel insulator can be used to block boron diffusion. As shown in FIG. 4, these can be formed either by growing a silicon dioxide layer in step S404 and implanting nitrogen to form an oxynitride in step S406, or by thermally growing a silicon nitride layer on silicon or on a very thin SiO₂ base in step S408. In either event, the tunnel insulator is preferably on the order of 8-12 Å thick.

As further shown in FIG. 4, the polysilicon layer is next formed. Preferably, the polysilicon layer is about 500-1000 Å thick, and the poly doping is in the range of 2 to 20×10²⁰/cm³, providing a sheet resistance on the order of 50-200 ohms/square. As shown, the deposition preferably takes place in two steps S410 and S412. First, the poly is deposited at 670° C. using conventional CVD decomposition of silane or disiane. Next, the poly is densified with a 30 second 1050° C. anneal.

It should be apparent that additional processing steps can be performed to form contacts on the front and/or back surface of the cell.

In accordance with further aspects, embodiments of the present invention use a polysilicon tunnel junction to replace the deep diffusion in a selective emitter type solar cell. This eliminates the deep diffusion and associated patterning step, and enables the remaining patterning to be done without critical alignment or fine features.

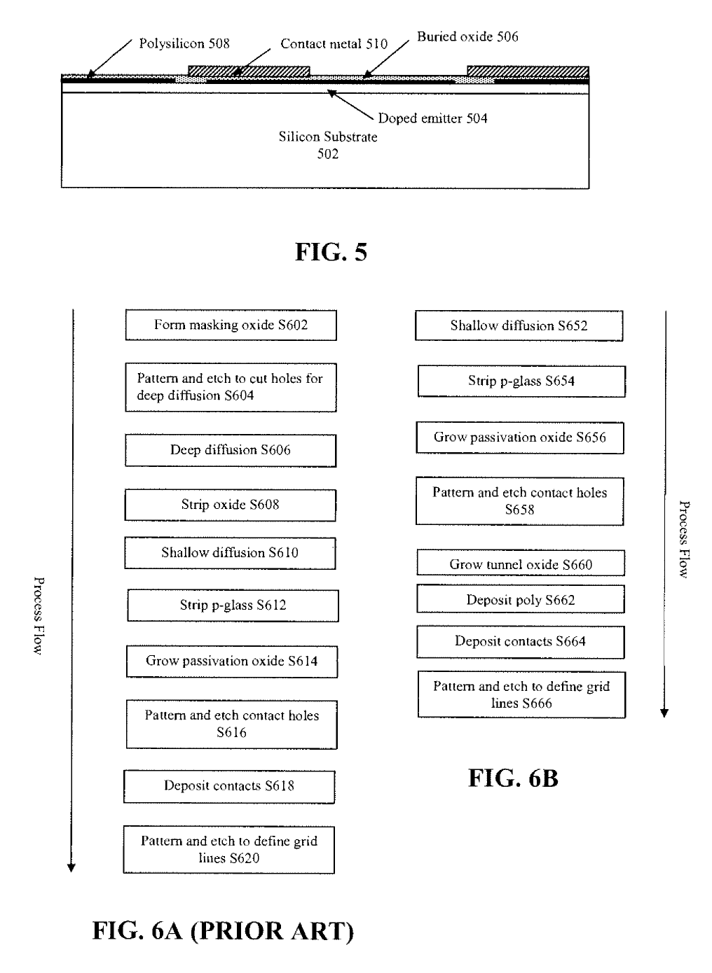

A structure according to these embodiments of the invention is shown in FIG. 5. As shown, it includes a doped emitter layer 504 formed over a silicon substrate 502. A buried oxide layer 506 is formed on emitter layer 504 with contact holes etched in it between portions of polysilicon layer 508 and contacts 510. According to further aspects of the invention, a thin tunnel oxide layer (not shown) is also included between polysilicon layer 508 and emitter layer 504. Further details regarding this structure will become apparent from the process flow descriptions below.

To assist in understanding aspects of the invention, a conventional process flow is shown in FIG. 6A and a process flow according to these embodiments of the invention is shown in FIG. 6B.

As shown in FIG. 6A, in the prior art, the deep diffusion step S606 must be done in the contact areas, requiring a prior masking oxide formation step S602 and patterning step S604. After the subsequent deep diffusion step S606, the masking oxide is stripped in S608. The remaining processing steps S610 to S620 are then performed, which to the extent are helpful to understanding the invention and are similar to those of the invention, will be described below.

As shown in FIG. 6B, the first three steps in the conventional process are eliminated in the new process, which begins with the shallow emitter 504 diffusion in step S652, and which can be performed in many ways known to those skilled in the solar cell arts. A passivation oxide 506 is then formed in step S656, and holes etched in it in step S658. Differently from the prior art, this step S658 can be performed as disclosed in co-pending PCT application No. PCT/US09/31868, as well as other ways known to those skilled in the solar cell arts. Because the contacts themselves are passivated, it is not necessary to restrict the hole size to 2-3 μm, and much larger holes can be formed. This enables the patterning step to be done using screen printing rather than lithography.

Further different from the conventional process, a thin tunnel oxide is then grown in step S660, using processes such as Applied Materials' ISSG. This oxide is on the order of 12 Å thick, and is preferably nitrided to improve diffusion barrier properties. Next, in step S662, a thin polysilicon layer 508 is then deposited, which is on the order of 200-500 Å thick. The thin poly is transparent, and absorbs only a very small fraction of the incoming light. The polysilicon, or alternately, the oxide/polysilicon combination, provides contact passivation. Further passivation may be obtained by offsetting the metal conductor lines from the contact holes, so that the underlying oxide isolates the contacts 510 from the emitter 504.

The metal contacts 510 are then formed in steps S664 and S666. Note that because the poly is conductive, these need not be aligned over the contact holes, but must only be close to the contact holes. Therefore, fine aligned lithography is not needed in this step.

According to further aspects, the present inventors recognize that silicon nitride films have been considered for surface passivation in solar cells. These films are often charged in order to invert the surface, reducing the concentration of majority carriers at the surface and thereby suppressing recombination in surface traps. It is thought that films deposited using the most common methods—plasma-enhanced chemical vapor deposition (PE-CVD) and sputtering—may have surface damage due to initiation of the plasma, which somewhat degrades the passivation performance of these films. The issue is that there is no film present to protect the surface when the plasma first turns on.

In a next preferred embodiment of the invention, therefore, a nitrided gate film is first formed on the solar cell surface. This can be done in a two step process. Following a surface clean and HF etch to remove native oxide, a thin SiO₂ layer is formed, typically 12 to 15 Å thick. This layer is then nitrided in a remote nitrogen plasma. Low energy nitrogen ions from a plasma inject themselves into the oxide, forming a thin top layer of silicon nitride. The interface with the silicon remains silicon dioxide, with good passivation properties. The presence of the silicon dioxide during the nitridation also protects the surface from plasma damage, overcoming the problem of surface plasma damage known in the prior art. This process can be implemented using commercially available technologies, for example, as the DPN process from Applied Materials. Depending on the process parameters, more or less nitrogen can be injected into the oxide. The nitrogen ions are positively charged, so a residual charge may be left in the oxide. This can be used to bias the surface. For example, if the substrate is P-type, the charge can be used to invert the surface, thereby further reducing recombination. However, this must be done in a controlled manner, as inversion will reduce the field across the oxide required to sustain a tunneling current as described later in the invention.

Next, a polysilicon layer is grown over the DPN layer, typically 2000 Å thick, This layer may be in-situ doped using arsenic or phosphorous for n-type, or boron for p-type. A unique advantage for solar cells is that the nitrided oxide now forms a diffusion barrier to prevent diffusion of the dopant into the underlying silicon. In other cases, the poly may be doped using plasma immersion ion implantation, although a high temperature annealing step is then required to activate dopants. In the preferred embodiment the polysilicon layer is uniformly doped to minimize the resistance of the structure. Contacts are then added on the front and back to complete the structure as in conventional processing.

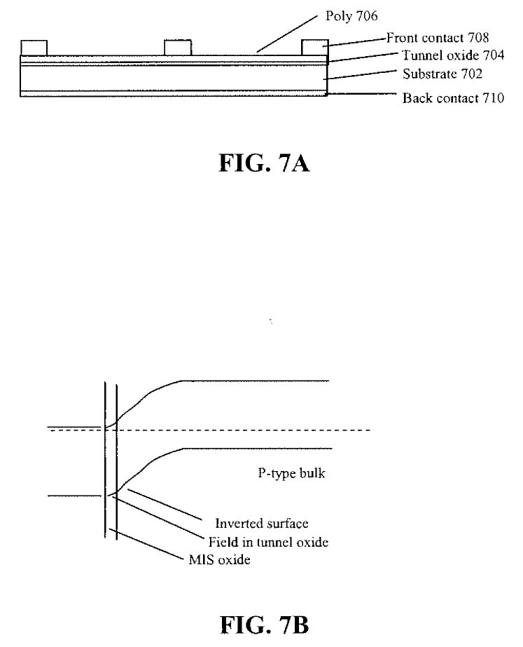

FIG. 7A shows the finished MIS solar cell structure using processes described above in accordance with these embodiments of the invention. As shown, it includes a tunnel oxide layer 704 formed over a substrate 702, a polysilicon layer 706 formed over the tunnel oxide layer 704, and front and back contacts 708 and 710, respectively. As discussed above, tunnel oxide layer 704 preferably is nitrided to include a thin DPN layer (not shown). FIG. 7B shows the band structure in this case. It should be noted that the field across the oxide is increased over the prior art case of FIG. 2B due to the nitride composition. The tunneling current will be increased, overcoming the series resistance limitation of prior art MIS solar cells.

Note that in some cases the poly contacts are formed as localized regions, as in FIG. 2A. However, because a thin polysilicon layer has relatively little light absorption, the polysilicon may be formed over a large region, or even the entire surface of the solar cell. This reduces the sheet resistance of the surface without adding undesired recombination at the interface between the poly and the cell (by virtue of the presence of the tunnel oxide). The benefit is again seen as reduced series resistance of the cell and improved efficiency.

In some cases, a doped layer can be formed in the top surface of the silicon before formation of the DPN layer. This is of the same conductivity type as the substrate and of lower doping than the polysilicon; for example, 10¹⁷ to mid-10¹⁸ atoms/cm³. The purpose is to form a region devoid of minority carriers to minimize recombination at the interface between the DPN layer and the substrate. This layer may be 1000 to 2000 Å thick, and may be formed using gaseous diffusion. However, as noted above, this doping will reduce the field across the dielectric, so a lower doping is preferred if it is used.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A solar cell comprising:
a substrate;
a tunnel dielectric that is nitrided formed over the substrate, and
a doped polysilicon layer formed over the nitrided tunnel dielectric.

2. A solar cell as in claim 1 wherein the tunnel dielectric is less than 20 angstroms thick.

3. A solar cell as in claim 1 wherein the tunnel dielectric is formed through nitridation of a layer of silicon dioxide.

4. A solar cell as in claim 1 wherein the tunnel dielectric is formed through thermal nitridation.

5. A solar cell as in claim 1 wherein boron is used as a dopant in the polysilicon.

6. A solar cell emitter contact comprising:
a dielectric layer formed over an emitter having an opening formed therein;
a nitrided layer formed over the dielectric layer and in the opening;
a polysilicon layer overlapping the opening; and
metallization in contact with the polysilicon layer.

7. A solar cell emitter contact as in claim 6 wherein the polysilicon layer is doped.

8. A solar cell emitter contact as in claim 6 wherein the tunnel insulator is less than 20 Angstroms thick.

9. An MIS solar cell comprising:
a substrate;
a polysilicon layer over the substrate;
an insulating layer between the substrate and the polysilicon layer that includes a nitrided diffusion barrier.

10. A MIS solar cell as in claim 9 wherein the diffusion barrier comprises a nitrided oxide.

11. A MIS solar cell as in claim 9 wherein the polysilicon layer has an opposite doping type from the substrate.

12. A MIS solar cell as in claim 11 wherein the substrate includes a surface doping layer.

13. A MIS solar cell as in claim 12 wherein the surface doping layer is of the same conductivity type as the substrate.

14. A MIS solar cell as in claim 10 wherein the nitrided oxide is charged so as to control the surface carrier concentration.

15. A method of fabricating the solar cell of claim 1, wherein during processing of the polysilicon layer, the nitrided tunnel dielectric blocks diffusion from the polysilicon layer into the substrate.

16. A method of fabricating the solar cell emitter contact of claim 6, wherein the emitter is formed by a single shallow diffusion process.

17. A method of fabricating the MIS solar cell of claim 9, wherein during processing of the polysilicon layer, the nitrided diffusion barrier blocks diffusion from the polysilicon layer into the substrate.
